(19) United States
(12) Patent Application Publication
(10) Pub. No.: US 2010/0309639 A1
(43) Pub. Date: Dec. 9, 2010

(54) CIRCUIT BOARD MODULE AND ELECTRONIC APPARATUS

(75) Inventor: Shotaro Nagaike, Kanagawa (JP)

Correspondence Address: Seed Intellectual Property Law Group PLLC, 701 Fifth Avenue, Suite 5400, Seattle, WA, 98104, US

(73) Assignee: PANASONIC CORPORATION, Osaka (JP)

(21) Appl. No.: 12/863,172

(22) PCT Filed: Oct. 23, 2008
(86) PCT No.: PCT/JP2008/003010

§ 371 Date: Jul. 15, 2010

(30) Foreign Application Priority Data
Jan. 15, 2008 (JP) 2008-005460

(51) Int. Cl. H05K 7/00

(52) U.S. Cl. 361/760

(57) ABSTRACT

A circuit board module includes: a board having a mounting surface; a frame member which is mounted on the mounting surface; an electronic component which is mounted on the mounting surface and which is provided inside the frame member; a resin portion which is embedded in the frame member; and a display device disposed on an opposite surface opposite to the mounting surface of the board. The display device is substantially equal in size to the frame member, and disposed at a position of the opposite surface which substantially corresponds to the frame member.

### TECHNICAL FIELD

The present invention relates to a circuit board module and an electronic apparatus.

### BACKGROUND

As shown in FIG. 6, an electronic apparatus 100 such as a portable telephone includes a circuit board 102 housed in a casing 101. A main display unit 103 of the circuit board 102 is opposed to a main display opening 101A of the casing 101 through a main cushion member 104, and a sub-display unit 106 of the circuit board 102 is opposed to a sub-display opening 101B of the casing 101 through a sub-cushion member 107.

In the circuit board 102, a tubular frame member 110 is connected to a connecting terminal 111 of a base member 108 through a solder so as to surround electronic components 109 mounted on the base member 108. After a filler 112 filled in the frame member 110 is solidified, the frame member 110 is covered with a shield cover 113. The main display unit 103 (a holder 103A and a liquid crystal main body 103B) is fixed to the shield cover 113. Furthermore, the sub-display unit 106 (a holder 106A and a liquid crystal main body 106B) is disposed on the rear surface of the base member 108.

In the circuit board 102, the filling amount of the filler 112 is previously determined so that the top face 112A of the filler 112 reaches the same level as the top portion 110A of the frame member 110. After the filler 112 is solidified, therefore, the top face 112A of the filler 112 supports the main display unit 103 through the shield cover 113.

Among circuit boards, meanwhile, there is a circuit board which is configured so that an electronic component is housed in a hole of a holder disposed on a base member, and the holder supports a main display unit (for example, see Patent Reference 1).

Patent Reference 1: JP-A-10-115835

### DISCLOSURE OF THE INVENTION

### Problems to be Solved by the Invention

Recently, from the viewpoints of portability, usability, and the like, an electronic apparatus is requested to be thinner. In the electronic apparatus 100 shown in FIG. 6, however, to place the main display unit 103 and the sub-display unit 106 on the front and rear of the base member through holders, respectively, is disadvantageous in thinning.

In the case of Patent Reference 1, the surface of the holder which houses the electronic component is formed as a concavo-convex shaped surface because of the electronic component. When the main display unit is placed on the concavo-convex shaped surface, in the case where a predetermined pressing force is applied to the electronic apparatus, stress concentration occurs in the main display unit, and a failure such as breakage of glass of the main display unit.

The invention was made in order to solve the above-described problems, and an object thereof is to provide a circuit board module and electronic apparatus which can be thinned even in the case where a thick electronic component such as a display device is mounted on a board.

### Means for Solving the Problems

A circuit board module of the invention includes: a board having a mounting surface; a first frame member which is mounted on the mounting surface; a second frame member which is provided inside the first frame member, and which is mounted on the mounting surface; an electronic component which is provided between the first frame member and the second frame member, and which is mounted on the mounting surface; a resin portion which is provided between the first frame member and the second frame member, and which closely contacts the electronic component, the mounting surface, the first frame member, and the second frame member; and a lid portion which covers the electronic component and the resin portion, which has a hole in a part corresponding to the second frame member, and which is connected to the first frame member.

According to the configuration, in a region defined by the hole of the lid portion and the inside of the second frame member, a space (hereinafter, referred to as “vertical space”) which is formed in the thickness (upper and lower) direction of the board is disposed to extend from the mounting surface of the board to the outside of the lid portion while being passed through the inside of the second frame member and the hole of the lid portion. Therefore, for example, an electronic component which is so thick that it cannot be housed between the mounting surface of the board and the lid portion, or the like can be mounted by using the vertical space.

In the circuit board module of the invention, a height from the board to an upper surface of the second frame member is lower than a height from the board to an upper surface of the first frame member.

According to the configuration, the height from the board to the upper surface of the second frame member is lower than that from the board to the upper surface of the first frame member, and hence the ceiling surface of the lid portion which is placed on the upper surface of the first frame member is not pushed up by the second frame member. As a result, a situation where the lid portion is disengaged by the pushing-up operation can be avoided, and hence the connection between the lid portion and the first frame member is ensured.

The circuit board module of the invention includes a first display device provided inside the second frame member.

According to the configuration, even when the first display device is so thick that it cannot be housed between the mounting surface of the board and the lid portion, the first display device can be housed in the above-mentioned vertical space. Namely, at least a part of the first display device is housed inside the second frame member, and the remaining part protrudes from the hole of the lid portion, whereby even when the height from the board to the lid portion is low, the first display device can be mounted on the circuit board module. Therefore, as compared with the case where thick components are placed while being piled up on the lid portion, for example, the height dimension of the circuit board module can be suppressed to a small value, and the module can be thinned.

In the circuit board module of the invention, the first display device is attached to the hole of the lid portion in a state where at least a part thereof is housed inside the second frame member.

Also in the case of the above-described configuration, at least a part of the first display device is housed inside the second frame member, whereby, as compared with the case where the entire first display device is placed on the lid portion, the height dimension of the whole circuit board module can be suppressed to a small value.

In the circuit board module of the invention, the first display device is mounted on the board in a state where at least a part thereof is passed through the hole so as to protrude to an outside of the lid portion.

Also in the case of the above-described configuration, at least a part of the first display device is housed inside the second frame member, whereby, as compared with the case where the entire first display device is placed on the lid portion, the height dimension of the whole circuit board module can be suppressed to a small value.

The circuit board module of the invention includes a second display device which is substantially equal in size to the first frame member and which is provided at a position which substantially corresponds to the first frame member along a surface opposite to the mounting surface of the board.

The opposite surface on which substantially no electronic component is placed has a small degree of concavity and convexity. According to the configuration, along the opposite surface having a small degree of concavity and convexity, the second display device which is substantially equal in size to the first frame member is placed at a position which substantially corresponds to the first frame member, along the opposite surface having a small degree of concavity and convexity. Therefore, when the second display device is pressed from the outside, for example, the whole first frame member can uniformly receive the force through the opposite surface having a small degree of concavity and convexity. Furthermore, a resin is embedded in the whole first frame member, and also the rigidity of the first frame member is enhanced. Even in the case where the second display device contains an easily breakable member, therefore, the possibility that the member is broken can be suppressed to a low level.

An electronic apparatus of the invention includes the above-described circuit board module.

### ADVANTAGES OF THE INVENTION

According to the invention, it is possible to provide a circuit board module that has the lid portion which covers the electronic component disposed outside the second frame member, and the resin portion, and in which the hole is disposed at a position corresponding to the second frame member, that, even in the case where a thick electronic component such as the first display device is to be mounted on the side of the board, enables at least a part of the electronic component to be housed in the space which is ensured inside the second frame member, and that can be correspondingly thinned, and also an electronic apparatus including this.

### BRIEF DESCRIPTION OF DRAWINGS

FIG. 1 is an exploded perspective view showing a circuit board module of an embodiment of the invention.

FIG. 2 is a sectional view taken along arrow II-II of FIG. 1.

FIG. 3 is a main-portion cutaway sectional view showing a height relationship between a first frame member and a second frame member in the circuit board module of the embodiment of the invention, and the like.

FIG. 4 is a main-portion sectional view showing a modification of the circuit board module of the embodiment of the invention.

FIG. 5 is a sectional view taken along arrow V-V of FIG. 4 and showing a modification of the circuit board module of the modification.

FIG. 6 is a main-portion sectional view showing the structure of a board of a conventional portable terminal apparatus or the like.

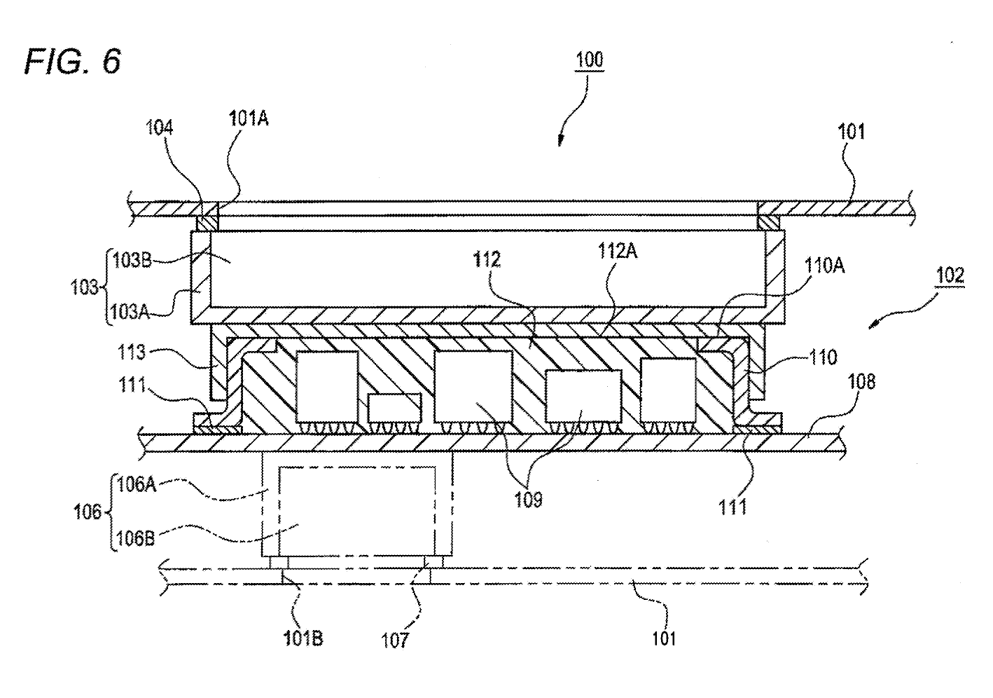

### DESCRIPTION OF REFERENCE CHARACTERS

1 board
2 electronic component
3 electronic component (first display device)
4 first frame member
5 second frame member
6 resin portion
7 lid portion
72 hole
10 circuit board module
h₁ height of wall from board to upper surface of first frame member
h₂ height of wall from board to upper surface of second frame member
D₁ first display device
D₂ second display device
Δh gap
S space

### BEST MODE FOR CARRYING OUT THE INVENTION

Hereinafter, an embodiment of the invention will be described in detail with reference to the accompanying drawings.

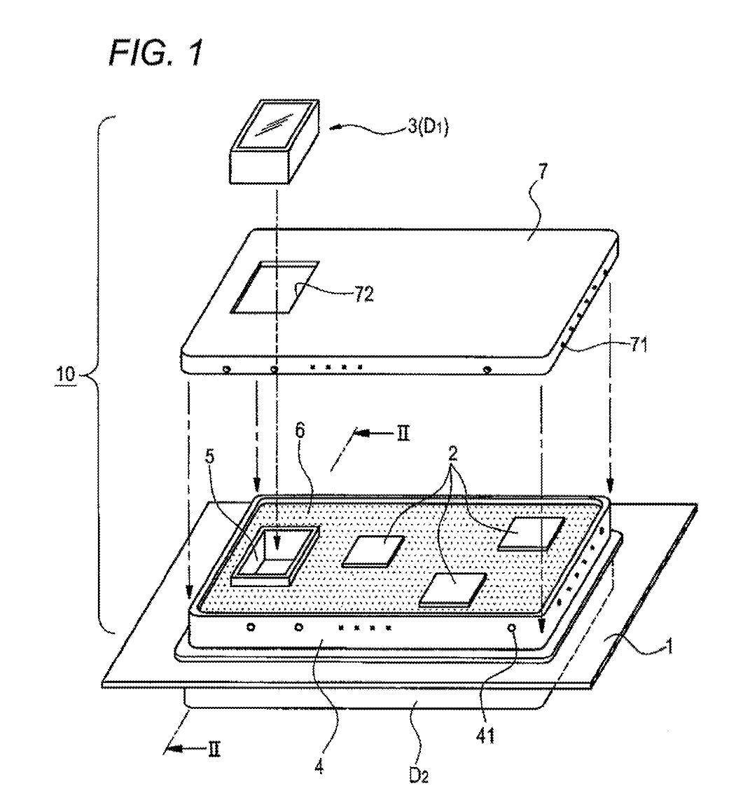

FIG. 1 shows a circuit board module 10 of the embodiment of the invention. The circuit board module 10 is disposed in a casing of a portable telephone which is one kind of an electronic apparatus, and which is not shown, and includes a board 1, electronic components 2, a first display device D₁ which is an electronic component 3, a first frame member 4, a second frame member 5, a resin portion 6, a lid portion 7, and a second display device D₂₋.

The board 1 is configured by a printed board which is thinner than usual one, or the like, and the electronic components 2, the lid portion 7, and the like are disposed on the side of one surface (a mounting surface: in FIG. 1, the upper surface). On the side of the opposite surface (in FIG. 1, the lower surface) opposite to the one surface of the board 1, a second display device D₂ which is configured by a liquid crystal, an organic EL, or the like, and which is a large display portion that is substantially equal in size to the first frame member 4 is mounted at a position which substantially corresponds to the first frame member 4.

The electronic components 2 are configured by, for example, electronic components which include a digital (electronic) circuit, and which are relatively thinner, and mounted in a region which is in the one surface of the board 1 functioning as the mounting surface, and which is inside the first frame member 4 that is a large frame, and outside the second frame member 5 that is a small frame.

The electronic component 3 is an electronic component which cannot be housed within the height from the mounting surface of the board 1 to the ceiling surface of the lid portion 7, and which is thicker than the usual electronic components 2 (that are relatively thinner). In the embodiment, the first display device D₁ is used as the electronic component, and attached to a hole 72 which described later, and which is in the lid portion 7. A part in the thickness direction of the first display device D₁ is housed inside the second frame member 5, and that of the upper side protrudes from the upper surface of the lid portion 7.

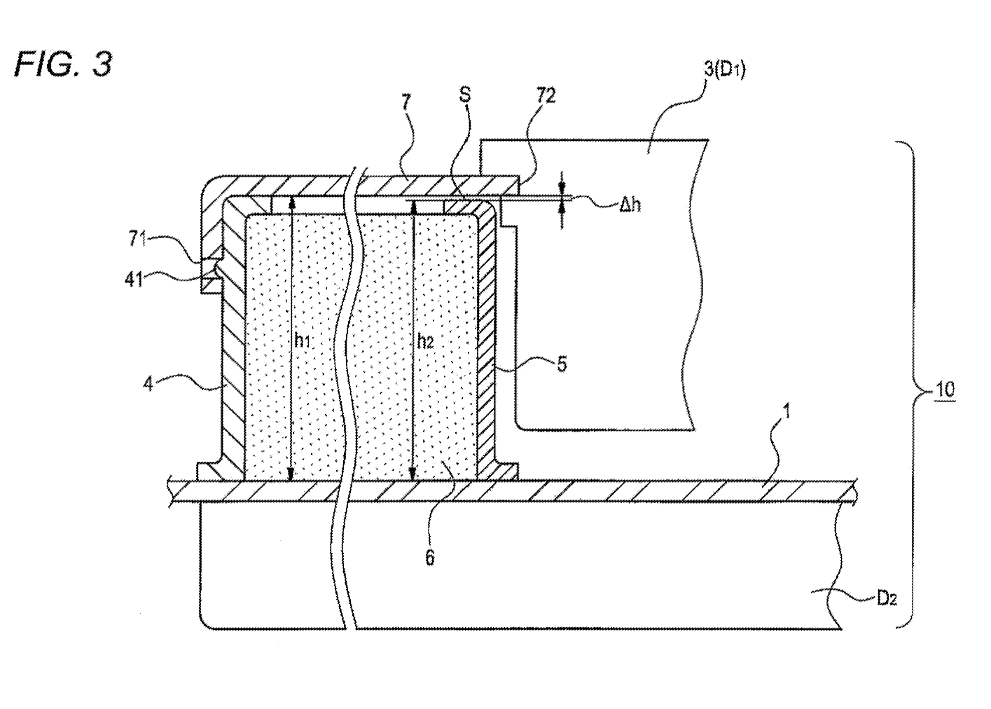

The first frame member 4 is disposed so as to surround the plurality of electronic components 2 which are mounted on the mounting surface of the board 1, and the resin portion 6 which is around the electronic components. Specifically, a large frame member which has a substantially rectangular section shape, and which exhibits a substantially rectangular tubular shape is mounted on the mounting surface which is one surface of the board 1. The first frame member 4 cooperates with the lid portion 7 to perform an electromagnetic shield (including a high-frequency shield) on the electronic components 2, thereby preventing electromagnetic radiation from leaking from the first frame member 4 and the lid portion 7 to the outside, and blocking unwanted radiation from entering from the outside. Therefore, the first frame member 4 is formed by a material which is electrically conductive. The bottom surface of the first frame member 4 is electrically connected to the board 1. As shown in FIG. 3, moreover, the first frame member is electrically connected also to the lid portion 7 to be configured so that the potential is lowered to the ground of the board 1. At the same time, in order to mechanically fix the lid portion 7 in a detachable manner, a plurality of contacts 41 are disposed over the whole circumference of the outer circumferential face (FIG. 3).

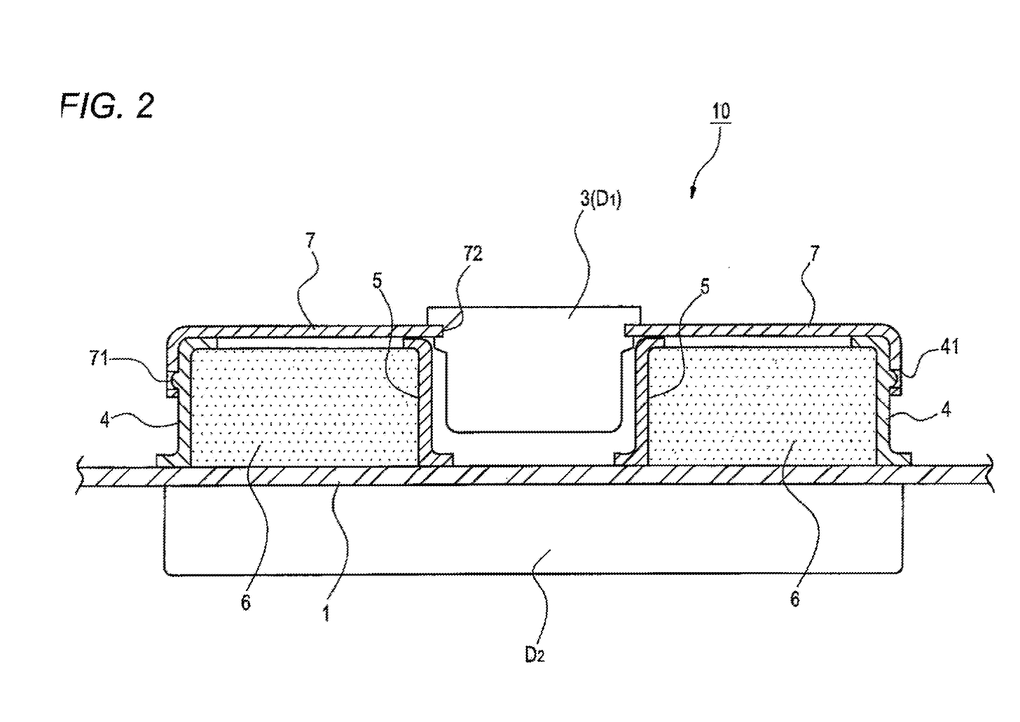

The second frame member 5 is a small frame which has a substantially rectangular section shape that is smaller than the first frame member 4, and which exhibits a substantially rectangular tubular shape, and particularly disposed on the mounting surface which is one surface of the board 1, and inside the first frame member 4. As shown in FIG. 2, namely, the second frame member 5 is placed correspondingly with the hole 72 which is described later, and which is in the lid portion 7, and immediately below the hole 72. The second frame member 5 is disposed so that the inside area surrounded by the second frame member 5 is substantially equal to the area of the hole 72, or the second frame member is slightly larger in area than the hole 72.

Also in the second frame member 5 in the embodiment, similarly with the first frame member 4, the bottom surface is electrically connected to the board 1 to be configured so that the potential is equal to the ground of the board 1.

In the invention, as shown in FIG. 3, moreover, the height (h₂) from the mounting surface of the board 1 to the upper surface of the second frame member 5 is lower than the height (h₁) from the mounting surface of the board 1 to the upper surface of the first frame member 4. As shown in FIG. 3, namely, the first frame member 4 and the second frame member 5 are formed so as to hold the relationship of Expression (1) with respect to the wall heights h₁, h₂.

[Exp. 1]

h₁>h₂ (1)

Therefore, the second frame member 5 does not push up the ceiling surface of the lid portion 7 which is placed to butt against the upper surface of the first frame member 4, and it is possible to avoid the lid portion 7 from being disengaged by the pushing-up operation. Therefore, the connection between the lid portion 7 and the first frame member 4 is more ensured.

The wall heights of the second frame member 5 and the first frame member 4 have the above-described relationship of Expression (1). As shown in FIG. 3, therefore, a space S configured by a small gap (Δh) is formed between the upper surface of the second frame member 5 and the ceiling surface of the lid portion 7. Accordingly, even when an external force is applied to the first display device D₁, for example, the lid portion 7 to which the device is attached is downward displaced by using the space S, whereby most of the external force is absorbed and the first display device D₁ can be avoided from being broken.

The resin portion 6 is between the first frame member 4 and the second frame member 5, and disposed so as to closely contact the electronic components 2, the mounting surface of the board 1, the first frame member 4, and the second frame member 5. As described above, the resin portion 6 is mounted on the one surface of the board 1, whereby, even when a reinforcement metal plate or the like is not additionally disposed and when the board 1 which is thinner than usual one is used, while the thinness is held, a certain degree of strength can be ensured at the same time with respect to the casing of the electronic apparatus such as a portable telephone. In other words, because of the resin portion 6 which is thinly formed on the one surface of the thin board 1, a certain degree of strength can be ensured, and at the same time the thinning can be realized, with respect to the casing portion of the portable telephone.

The resin portion 6 in the embodiment is formed by an appropriate thermosetting resin material. When the resin material of the resin portion 6 is filled on the one surface of the board 1 and thermoset in a heating oven, the resin material can be set without causing thermal expansion and thermal contraction. In other words, improvements for preventing warpage or the like from occurring after thermosetting are provided.

The lid portion 7 is configured so as to cover physically integrally the electronic components 2, the second frame member 5, and the resin portion 6, and, similarly with the first frame member 4, formed by an electrically conductive material to be provided with the electromagnetic shielding function. Therefore, leaking of electromagnetic radiation from the lid portion 7 and the first frame member 4 to the outside can be prevented from occurring, and unwanted radiation can be blocked from entering from the outside to the lid portion 7 and the first frame member 4.

In the lid portion 7 in the embodiment, in order to, as described above, mechanically fix the lid portion to the first frame member 4 in a detachable manner, and to, at the same time, electrically connect the lid portion to the first frame member 4, a large number of fitting holes 71 which are fitted to the contacts 41 of the first frame member 4 are disposed over the whole outer circumferential face. According to the configuration, as described above, the lid portion 7 is configured so as to have the same potential as the ground of the board 1 through the first frame member 4, and the potential of the ground is kept more constant. Namely, also an effect that the ground can be enhanced is provided.

In the lid portion 7, as described above, the hole 72 is opened correspondingly with the second frame member 5 and immediately above the second frame member 5, and, in other words, the open inside of the second frame member 5 and the hole 72 opened in the lid portion 7 are vertically continued to each other to form a large space (vertical space) in the vertical (upper and lower) direction. In the invention, the electronic component 3 which is so thick that it cannot be housed in the space between the mounting surface of the board 1 and the lid portion 7 is enabled to be placed by using the vertical space.

In the lid portion 7 in the embodiment, in order to fix the electronic component 3 which is placed by using the vertical space, the first display device D₁ which is the electronic component 3 is attached to the hole 72 as shown in FIG. 2. Even when the vertical space which is formed by the first frame member 4 and the lid portion 7 is thin, therefore, the first display device D₁ which is thicker than it can be placed in a fixed state. Moreover, the first display device D₁ is disposed in a non-contact state with respect to the mounting surface of the board 1, and configured so that it can be displaced with a certain degree of freedom in the thickness (upper and lower) direction by performing a displacement operation of the lid portion 7 such as bending. As a result, even when an external force such as described above is applied to the first display device D₁, the first display device D₁ is displaced together with the lid portion 7, whereby fragile components included in the first display device D₁, such as glass can be avoided from being broken.

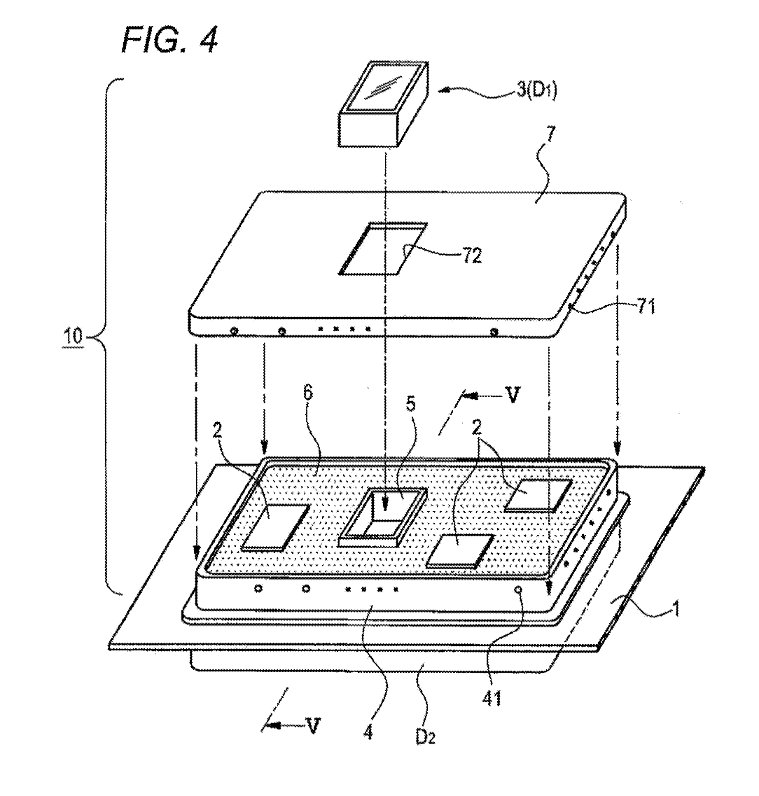

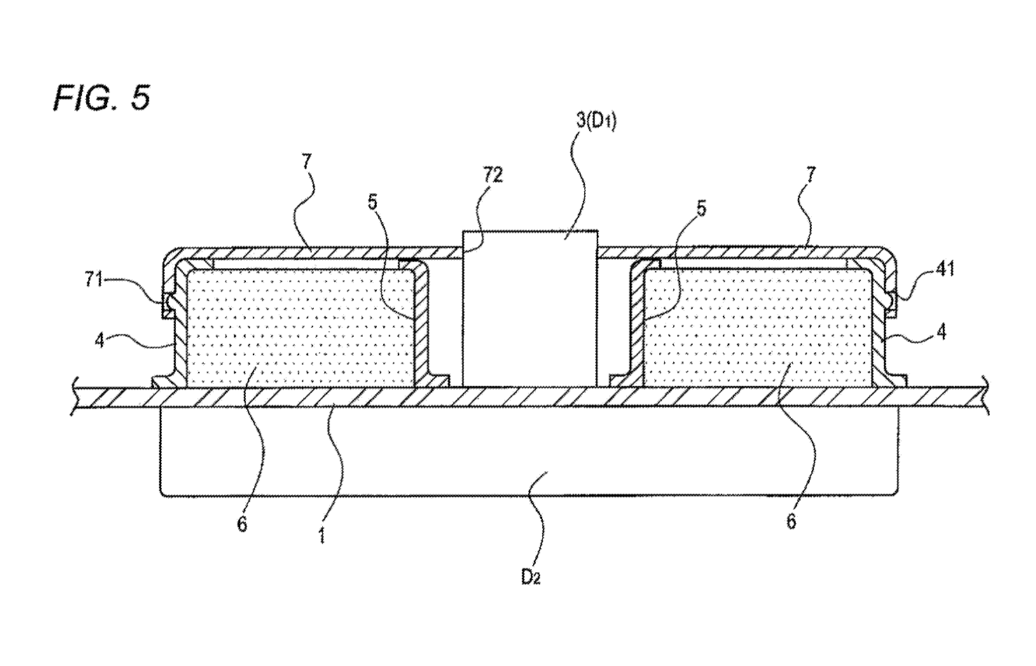

Since the first display device D₁ in the embodiment is in the non-contact state where it separates from the mounting surface of the board 1, the electrical connection with respect to the board 1 and the like is performed by disposing appropriate connecting means with respect to the board 1. In place of the configuration of the embodiment, as shown in FIGS. 4 and 5, for example, a configuration where the first display device D₁ is mounted directly on the mounting surface of the board 1 may be employed. In a circuit board module having the configuration, when an external force is applied to the first display device D₁, the external force is allowed to escape by using a bending operation of the board 1 itself although the effect is smaller than the embodiment. On the other hand, in the circuit board module shown in FIGS. 4 and 5, the electrical connection between the first display device D₁ and the board 1 can be performed easily as compared with the circuit board module of the embodiment.

In the circuit board module 10 of the embodiment, the opposite surface (in FIG. 1, the lower surface) in which a frame member is not disposed and substantially no electronic component is placed has a small degree of concavity and convexity. According to the configuration, along the opposite surface having a small degree of concavity and convexity, the second display device D₂ which is substantially equal in size to the first frame member 4 is placed at a position which substantially corresponds to the first frame member 4. Therefore, when the second display device D₂ is pressed from the outside, for example, the whole first frame member 4 can uniformly receive the force through the opposite surface having a small degree of concavity and convexity. Furthermore, the resin is embedded in the whole first frame member 4, and also the rigidity of the first frame member 4 is enhanced. Even in the case where the second display device D₂ contains an easily breakable member (such as glass), therefore, the possibility that the member is broken can be suppressed to a low level.

The embodiment has been described while assuming that the section shapes of the first frame member 4 and the second frame member 5 are substantially rectangular. The shapes are not restricted to be rectangular, and may be circular or polygonal.

The invention can be executed in various modes. In the embodiment, the circuit board module 10 is disposed in a casing of a portable telephone which is one kind of an electronic apparatus. As the portable telephone, the module can be disposed in casings of various kinds such as the straight type and the foldable type. As an electronic apparatus in which the circuit board module is disposed, in addition to the portable telephone, for example, the module can be disposed in a PDA (Portable Digital Assistant), a PHS (Personal Handyphone System), or other various electronic apparatuses.

Although various embodiments of the invention have been described, the invention is not limited to the matters described in the embodiments. In the invention, it is expected that those skilled in the art will change or apply the matters based on the description in the description and the well-known technique, and such a change or application is included in the range to be protected.

The application is based on Japanese Patent Application (No. 2008-005460) filed Jan. 15, 2008, and contents of which are incorporated herein by reference.

### INDUSTRIAL APPLICABILITY

The circuit board module of the invention has an effect that, even in the case where a thick electronic component or the like is to be mounted on the board, at least a part of the electronic component can be housed in the space which is ensured inside the second frame member, and the module can be correspondingly thinned, and is useful in disposition in, for example, a portable telephone, a PDA, a PHS, or other electronic apparatuses.

1.-7. (canceled)

8. A circuit board module comprising:
a board having a mounting surface;
a frame member which is mounted on the mounting surface;
an electronic component which is mounted on the mounting surface and which is provided inside the frame member;
a resin portion which is embedded in the frame member; and
a display device disposed on an opposite surface opposite to the mounting surface of the board,
wherein the display device is substantially equal in size to the frame member, and disposed at a position of the opposite surface which substantially corresponds to the frame member.

9. The circuit board module according to claim 8,
wherein the display device contains glass.

10. An electronic apparatus comprising the circuit board module according to claim 8.
